(19) United States
(12) Patent Application Publication
(10) Pub. No.: US 2025/0212369 A1
(43) Pub. Date: Jun. 26, 2025

(54) THERMAL COUPLING DEVICE FOR A COMMON MODE INDUCTOR

(71) Applicant: Valeo eAutomotive Germany GmbH, Erlangen (DE)

(72) Inventors: Christopher RICHE, Creteil Cedex (FR); Manuel FALGUIER, Creteil Cedex (FR); Aurelien POUILLY, Cergy Pontoise (FR)

(73) Assignee: Valeo eAutomotive Germany GmbH, Erlangen (DE)

(21) Appl. No.: 18/990,911

(22) Filed: Dec. 20, 2024

(30) Foreign Application Priority Data
Dec. 22, 2023 (FR) FR2314970

(51) Int. Cl. H05K 7/20; H01F 27/06; H01F 27/24

(52) U.S. Cl. CPC H05K 7/2039; H01F 27/06; H01F 27/24

(57) ABSTRACT

A thermal coupling device for a common mode inductor, configured to transfer heat to a heat sink. The device includes an annular prismatic ferrite core configured to be passed through by at least one electrical connector of an electronic component. A stand is secured to the heat sink, the ferrite core being in contact with the stand and the stand being configured to transfer the heat generated by the ferrite core to the heat sink. The thermal coupling device includes a clamping member configured to hold the ferrite core and the stand secured together, the ferrite core, the stand and the clamping member extending orthogonally with respect to the longitudinal reference plane of the electrical connector.

### TECHNICAL FIELD

The present invention relates to the technical field of electric or hybrid vehicles.

More specifically, the invention relates to the technical field of voltage converters and the cooling of electronic components forming such voltage converters.

### PRIOR ART

An electric or hybrid vehicle comprising a voltage converter, notably an inverter, configured to convert a DC voltage from a high-voltage battery into an AC voltage in order to supply alternating voltage to an electric motor is known from the prior art. In order to ensure the operation of such a voltage converter within an electromagnetic environment without generating electromagnetic interference that may adversely affect other electrical systems of said vehicle, the voltage converter notably comprises an electromagnetic compatibility filter, commonly referred to as “EMC filter” by those skilled in the art.

To perform this filtering function, the EMC filter comprises a plurality of capacitors. These capacitors, during the filtering, dissipate energy in the form of thermal energy. It is then known to combine these capacitors with inductors, commonly referred to as “common mode inductors” by those skilled in the art, making it possible to limit the heating of the capacitors of the EMC filter. Nevertheless, the common mode inductors themselves require cooling, in particular the common mode inductor at the output of the filtering device, that is to say connected notably to a link capacitor.

The invention aims to remedy any drawback of the prior art, by notably proposing a thermal coupling device configured to cool a common mode inductor.

### PRESENTATION OF THE INVENTION

More specifically, a subject of the invention is a thermal coupling device for a common mode inductor, configured to transfer heat to a heat sink, the device comprising:
an annular prismatic ferrite core configured to be passed through by at least one electrical connector of the electronic component extending at least partially along a longitudinal reference plane, the ferrite core being configured to generate a magnetic field induced by an electric current flowing in the electrical connector of the electronic component;
a stand secured to the heat sink, the ferrite core being in contact with the stand, the stand being configured to transfer the heat generated by the ferrite core to the heat sink.

The thermal coupling device is noteworthy in that it comprises a clamping member configured to hold the ferrite core and the stand secured together, the ferrite core, the stand and the clamping member extending orthogonally with respect to the longitudinal reference plane of the electrical connector. By virtue of such a combination of features, the thermal coupling device enables effective transfer of the heat generated by the ferrite core to the heat sink, by way of the stand. In such a configuration, the cooling of the common mode inductor is then optimized.

Advantageously, the stand and the clamping member have an annular prismatic structure and are coaxial with the ferrite core, the stand and the clamping member also being configured to be passed through by the electrical connector. In such a configuration, the mechanical strength of the mechanical coupling device is improved, the ferrite core, the stand and the clamping member having a similar geometrical structure. Furthermore, the compactness of such a device is improved, all of the components of the coupling device being passed through by the electrical connector.

Advantageously, the stand comprises a substantially planar base extending parallel to the reference plane, said base of the stand being in surface contact with the heat sink. In such a configuration, the thermal transfer of heat to the heat sink is improved, as is the fastening of the stand with respect to the heat sink.

Advantageously, the coupling device comprises a thermally conductive filler material, said material being interposed between the base and the heat sink. Such a material optimizes the draining of heat energy to the heat sink.

Advantageously, the clamping member is formed by a leaf spring secured to the base of the stand. In such a configuration, the holding in position of the ferrite core with respect to the stand is improved.

Advantageously, the ferrite core is in one piece. In such a configuration, the mechanical strength of the coupling device is further improved.

Advantageously, an annular groove is provided in the stand, the ferrite core being accommodated in the groove of the stand. In such a configuration, the contact surface for thermal exchange between the ferrite core and the stand is increased significantly, improving the cooling of the ferrite core.

Advantageously, the thermal coupling device comprises a thermally conductive filler material, said material being interposed between the stand and the ferrite core. Such a material optimizes the draining of heat energy to the stand.

According to another aspect of the invention, the latter relates to an item of electrical equipment comprising:
at least one electronic component;
a heat sink;
at least one thermal coupling device as described above.

According to another aspect of the invention, the latter relates to a method for assembling an item of electrical equipment as described above, comprising:
fastening the stand of the thermal coupling device to the heat sink orthogonally with respect to a longitudinal reference plane;
putting the ferrite core of the thermal coupling device in position in contact with the stand;
holding the ferrite core in position in contact with the stand by way of the clamping member of the thermal coupling device;
passing the electrical connector of the electronic component through a through-hole in the ferrite core such that the electrical connector extends at least partially in the longitudinal reference plane.

### PRESENTATION OF THE FIGURES

The invention will be better understood from reading the following description, which is given solely by way of example, and with reference to the attached drawings that are given by way of non-limiting examples, in which identical references are given to similar objects and in which:

FIG. 1 is a schematic representation in isometric perspective of an item of electrical equipment according to a first aspect of the invention;

FIG. 2 is a schematic representation in isometric perspective of a coupling device according to another aspect of the invention;

FIG. 3 is a schematic representation in top view of a detail of the item of electrical equipment in FIG. 1.

It should be noted that the figures set out the invention in detail so as to allow the invention to be implemented; although they are not limiting, said figures are used in particular to better define the invention where appropriate.

### DETAILED DESCRIPTION OF THE INVENTION

The invention notably relates to an item of electrical equipment 1 such as a voltage converter, for example an inverter. The item of electrical equipment 1 comprises a body delimiting a housing and a cover. FIG. 1 illustrates the item of electrical equipment 1 in a configuration with the cover removed.

The item of electrical equipment 1 notably comprises at least one electronic component 3 disposed in the housing and requiring cooling to ensure the operation thereof. The electronic component 3 may notably be a capacitor, in particular a capacitor of an EMC filter. The electronic component 3 comprises at least one electrical connector extending at least partially along a longitudinal reference plane. For cooling, the heat generated by the electronic component 3 is transmitted to a heat sink 5 of the item of electrical equipment 1. In this case, the heat sink 5 is formed by the body of the item of electrical equipment 1.

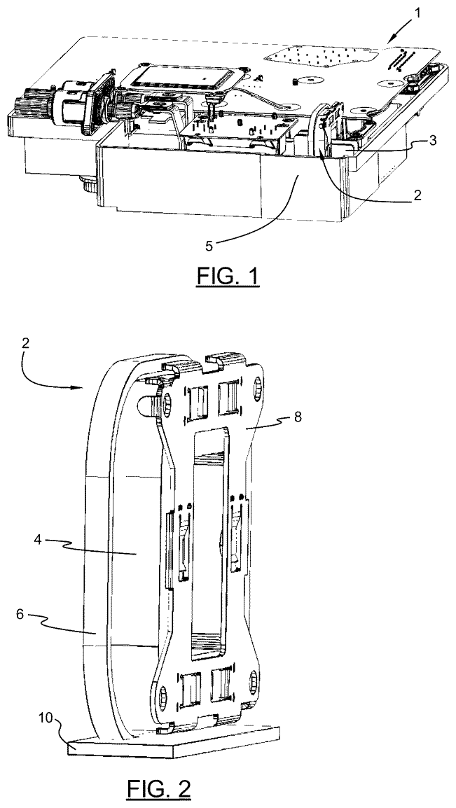

The item of electrical equipment 1 comprises a thermal coupling device 2 configured to transfer heat. The thermal coupling device 2 is illustrated in FIG. 2. The thermal coupling device 2 comprises a ferrite core 4. The ferrite core 4 is prismatic and annular, and is configured to be passed through by at least one electrical connector of the electronic component 3, preferably by two electrical connectors, this configuration being referred to as “common mode” by those skilled in the art. In other words, a through-hole is provided in the ferrite core 4, the electrical connector passing through the through-hole. The ferrite core 4 is configured to generate a magnetic field induced by the electric currents flowing in the electrical connectors of the electronic component 3 that pass through said core, at the same time generating heat through the Joule effect.

Furthermore, the thermal coupling device 2 comprises a stand 6 secured to the heat sink 5, the ferrite core 4 being in contact with the stand 6. The stand 6 is configured to transmit, by conduction, the heat generated by the ferrite core 4 to the heat sink 5. In order to hold the ferrite core 4 in position on the stand 6, the thermal coupling device 2 further comprises a clamping member 8. Thus, the stand 6, the ferrite core 4 and the clamping member 8 extend orthogonally with respect to the longitudinal reference plane of the electrical connector of the electronic component 3. By virtue of such a combination of features, the thermal coupling device 2 enables effective transfer of the heat generated by the ferrite core 4 to the heat sink 5, by way of the stand 6. In such a configuration, the cooling of the core 4 is maximized. Due to the fact that it channels the heat generated by other components of the item of electrical equipment 1, the ferrite core 4 is then referred to as “victim core”. Such a clamping member 8 makes it possible to effectively press the ferrite core 4 against the stand 6, maximizing the thermal conduction and ensuring mechanical strength of the entire thermal coupling device 2. Lastly, the “standing” arrangement of the thermal coupling device 2 makes it possible to meet different space constraints, notably different from a “lying” configuration of the ferrite core 4. Advantageously, the thermal coupling device comprises a thermally conductive filler material, said material being interposed between the base 10 and the heat sink 5. Such a material interposed in this way optimizes the draining of heat energy to the heat sink 5.

In the embodiment described in FIG. 2, the stand 6 and the clamping member 8 have an annular prismatic structure and are coaxial with the ferrite core 4. Thus, the stand 6 and the clamping member 8 are also configured to be passed through by the electrical connector of the electronic component 3. In addition to enabling better mechanical strength of the thermal coupling device 2, this configuration also maximizes the thermal conduction exchange surface between the ferrite core 4 and the stand 6. Furthermore, the compactness of the device is improved.

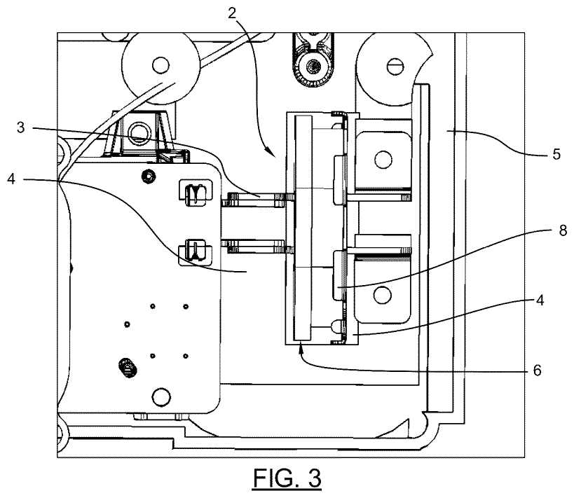

The stand 6 preferably comprises a base 10. The base 10, which is substantially planar, extends parallel to the longitudinal reference plane, as illustrated in FIG. 3. The base 10 enables surface contact with the heat sink 5. The thermal transfer of heat to the heat sink 5 is improved. The fastening of the stand 6, vertically with respect to the heat sink 5, is also improved with such a base 10. Advantageously, the thermal coupling device 2 comprises a thermally conductive filler material, said material being interposed between the stand 6 and the ferrite core 4. Such a material interposed in this way optimizes the draining of heat energy to the stand 6.

Further preferably, the clamping member 8 is formed by a leaf spring, secured to the base 10 and to the stand 6. The holding in position of the ferrite core with respect to the stand is improved. The leaf spring has the advantage of exerting a substantially uniform pressure on the ferrite core 4, by adapting to the hardness and to the small elastic deformability of the ferrite with respect to the other components of the item of electrical equipment 1.

The stand 6 may comprise a groove provided in said stand 6. In such a configuration, the ferrite core 4 is accommodated in the groove of the stand. The contact surface for thermal exchange between the ferrite core 4 and the stand 6 is then further increased, further improving the cooling of the ferrite. In order to mount the thermal coupling device 2 in the housing of the item of electrical equipment 1, the stand 6 is first fastened to the heat sink 5, orthogonally with respect to a longitudinal reference plane. The ferrite core 4 is mounted in contact with the stand 6, then the ferrite core 4 is held against the stand 6 by the clamping of the clamping member 8 on the stand 6. The electrical connector of the electronic component 3 is then passed through the through-hole in the ferrite core 4, then connected to other components of the item of electrical equipment 1, for example a link capacitor.

It will moreover be noted that the invention is not limited to the embodiments described above. Specifically, it will be apparent to those skilled in the art that various modifications may be made to the embodiment described above, in light of the teaching that has just been disclosed to them.

In the detailed presentation of the invention that is given above, the terms used should not be interpreted as limiting the invention to the embodiment set out in the present description, but should be interpreted as including any equivalents provision of which is within the capabilities of those skilled in the art by applying their general knowledge to the implementation of the teaching that has just been disclosed to them.

1. Thermal coupling device for a common mode inductor, configured to transfer heat to a heat sink, the device comprising:
an annular prismatic ferrite core configured to be passed through by at least one electrical connector of the electronic component extending at least partially along a longitudinal reference plane, the ferrite core being configured to generate a magnetic field induced by an electric current flowing in the electrical connector of the electronic component;
a stand secured to the heat sink, the ferrite core being in contact with the stand, the stand being configured to transfer the heat generated by the ferrite core to the heat sink;
the thermal coupling device being characterized in that it comprises a clamping member configured to hold the ferrite core and the stand secured together, the ferrite core, the stand and the clamping member extending orthogonally with respect to the longitudinal reference plane of the electrical connector.

2. Thermal coupling device according to claim 1, wherein the stand and the clamping member have an annular prismatic structure and are coaxial with the ferrite core, the stand and the clamping member also being configured to be passed through by the electrical connector.

3. Thermal coupling device according to claim 1, wherein the stand comprises a substantially planar base extending parallel to the reference plane, said base of the stand being in surface contact with the heat sink.

4. Thermal coupling device according to claim 3, comprising a thermally conductive filler material, said material being interposed between the base and the heat sink.

5. Thermal coupling device according to claim 3, wherein the clamping member is formed by a leaf spring secured to the base of the stand.

6. Thermal coupling device according to claim 1, wherein the ferrite core is in one piece.

7. Thermal coupling device according to claim 1, wherein an annular groove is provided in the stand, the ferrite core being accommodated in the groove of the stand.

8. Thermal coupling device according to claim 1, comprising a thermally conductive filler material, said material being interposed between the stand and the ferrite core.

9. Item of electrical equipment comprising:
at least one electronic component;
a heat sink;
at least one thermal coupling device according to claim 1.

10. Method for assembling an item of electrical equipment according to claim 9, comprising:
fastening the stand of the thermal coupling device to the heat sink orthogonally with respect to a longitudinal reference plane;
putting the ferrite core of the thermal coupling device in position in contact with the stand;
holding the ferrite core in position in contact with the stand by way of the clamping member of the thermal coupling device;
passing the electrical connector of the electronic component through a through-hole in the ferrite core such that the electrical connector extends at least partially in the longitudinal reference plane.

11. Thermal coupling device according to claim 2, wherein the stand comprises a substantially planar base extending parallel to the reference plane, said base of the stand being in surface contact with the heat sink.

12. Thermal coupling device according to claim 4, wherein the clamping member is formed by a leaf spring secured to the base of the stand.

13. Thermal coupling device according to claim 2, wherein the ferrite core is in one piece.

14. Thermal coupling device according to claim 2, wherein an annular groove is provided in the stand, the ferrite core being accommodated in the groove of the stand.

15. Thermal coupling device according to claim 2, comprising a thermally conductive filler material, said material being interposed between the stand and the ferrite core.

16. Item of electrical equipment comprising:
at least one electronic component;
a heat sink;
at least one thermal coupling device according to claim 2.

17. Thermal coupling device according to claim 3, wherein the ferrite core is in one piece.

18. Thermal coupling device according to claim 3, wherein an annular groove is provided in the stand, the ferrite core being accommodated in the groove of the stand.

19. Thermal coupling device according to claim 3, comprising a thermally conductive filler material, said material being interposed between the stand and the ferrite core.

20. Item of electrical equipment comprising:
at least one electronic component;
a heat sink;
at least one thermal coupling device according to claim 3.
